(19) United States
(12) Patent Application Publication
(10) Pub. No.: US 2019/0165310 A1
(43) Pub. Date: May 30, 2019

(54) DISPLAY DEVICE

(71) Applicant: Japan Display Inc., Tokyo (JP)

(72) Inventor: Hiroumi KINJO, Tokyo (JP)

(21) Appl. No.: 16/167,601

(22) Filed: Oct. 23, 2018

(30) Foreign Application Priority Data
Nov. 28, 2017 (JP) 2017-227602

(51) Int. Cl. H01L 51/52; H01L 51/00; H01L 51/50; H01L 27/32; H01L 27/12

(52) U.S. Cl. CPC H01L 51/5246; H01L 51/0097; H01L 51/5281; H01L 27/3276; H01L 27/1255; H01L 51/5012

(57) ABSTRACT

A display device in an embodiment according to the present invention includes a base plate including a first region, a second region and a third region, a first film covering the first region, and a resin layer covering the third region. The base plate includes a first surface and a second surface opposite to the first surface, the first region is located on the first surface side and is arranged with a plurality of pixels, the second region is located on the second surface side and is arranged with a terminal part, the third region is located on the first surface side and between the first region and the second region, and an end surface facing the third region of the first film is roughened and the resin layer contacts the end surface.

### CROSS REFERENCE TO RELATED APPLICATIONS

This application is based upon and claims the benefit of priority from the prior Japanese Patent Application No. 2017-227602, filed on Nov. 28, 2017, the entire contents of which are incorporated herein by reference.

### FIELD

One embodiment of the present invention is related to a display device and one embodiment of the disclosed invention includes a sealing structure of a display device.

### BACKGROUND

Among display devices which have display panels which are flexible and can be bent, a display device is known in which a periphery region can be bent in order to reduce the periphery region (edge region) of a display screen.

### SUMMARY

A display device in an embodiment according to the present invention includes a base plate including a first region, a second region and a third region, a first film covering the first region, and a resin layer covering the third region. The base plate includes a first surface and a second surface opposite to the first surface, the first region is located on the first surface side and is arranged with a plurality of pixels, the second region is located on the second surface side and is arranged with a terminal part, the third region is located on the first surface side and between the first region and the second region, and an end surface facing the third region of the first film is roughened and the resin layer contacts the end surface.

### BRIEF DESCRIPTION OF DRAWINGS

FIG. 1 is a diagram showing a structure of a display device according to one embodiment of the present invention;

FIG. 2 is a perspective diagram showing a structure of a display device according to one embodiment of the present invention;

FIG. 3 is a perspective diagram showing a structure of a display device according to one embodiment of the present invention;

FIG. 4 is a cross-sectional diagram for explaining a form when a display device is bent by a bending region according to one embodiment of the present invention;

FIG. 5A and FIG. 5B are cross-sectional diagrams showing a structure of a first film arranged in a display device according to one embodiment of the present invention;

FIG. 6A to FIG. 6C are diagrams showing a form of a cross-section of a first film arranged in a display device according to one embodiment of the present invention;

FIG. 7 is a cross-sectional diagram schematically showing a stacked structure of a display device according to one embodiment of the present invention;

FIG. 8 is a cross-sectional diagram showing a structure of a pixel in a display device according to one embodiment of the present invention

FIG. 9 is a cross-sectional diagram showing a structure of display device according to one embodiment of the present invention

FIG. 10A and FIG. 10B are cross-sectional diagrams showing a structure of a first film arranged in a display device according to one embodiment of the present invention;

FIG. 11 is a perspective diagram showing a structure of a first film in a display device according to one embodiment of the present invention; and

FIG. 12 is a cross-sectional diagram for explaining a sealing structure of a display device.

### DESCRIPTION OF EMBODIMENTS

Hereinafter, the embodiments of the present invention will be described while referencing the drawings. However, the present invention may be implemented in many different ways, therefore interpretation should not be limited to the content exemplified in the embodiments below. In order to provide a clearer description, some components of the drawings such as the width, thickness, shape, etc. of each part are represented schematically. These drawings are merely examples and do not limit the interpretation of the present invention. In this specification and each of the drawings, elements similar to previously described elements are marked with the same symbols (numbers followed by a, b, and the like) and detailed descriptions are omitted accordingly. Furthermore, characters labeled as “first” and “second” are symbols used to distinguish each element, and do not have any further meaning unless otherwise specified.

In this specification, when certain components or regions are described as being “above” or “below” other components or regions, as long as there are no limitations, it does not necessarily mean they are directly above or below. This description includes cases in which a component or region is located higher or lower than another component or region. In other words, other components or regions are located between the component or region being described and the component or region above or below. Further, in the description below, unless otherwise noted, in a sectional view, the side on which the first film is located with respect to the pixel of the substrate will be described as “above” and the other side will be described as “below.”

As used throughout this disclosure, the singular forms “a,” “an,” and “the” include plural reference unless the context clearly dictates otherwise. Thus, for example, a reference to “a groove” includes a plurality of such grooves, as well as a single groove.

### First Embodiment

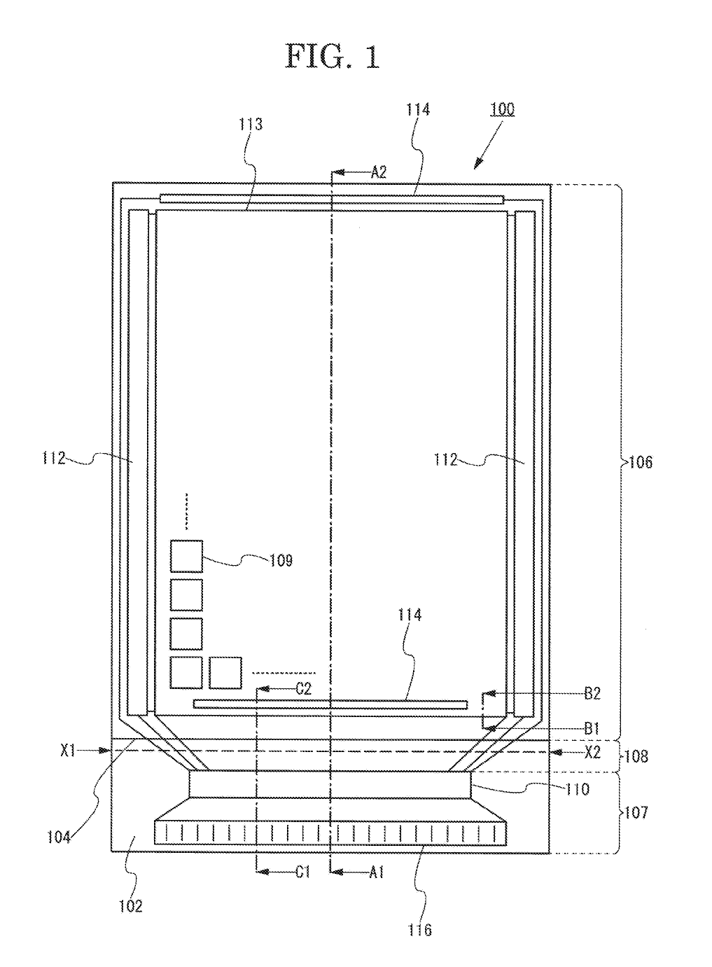

FIG. 1 shows a structure of a display device 100 according to one embodiment of the present invention. The display device 100 includes a base film 102 having a first surface and a second surface which is the opposite side surface to the first surface. The structural components which realize the main functions of the display device 100 are arranged on the first surface of the base film 102. The first surface of the base film 102 includes a first region 106 defined as a first region, a second region 107 arranged with a first drive circuit 110 and a terminal part 116, and a third region between the first region 106 and the second region 107.

The first region 106 includes a display region 113 arranged with a plurality of pixels 109. In addition, the first region 106 includes a common contact 114 for applying a constant potential to electrodes which form a pixel 109, and a second drive circuit 112 for outputting a scanning signal to a pixel 109. FIG. 1 shows a configuration in which the second drive circuit 112 is arranged along a first side of the display region 113 and along a second side facing to the first side in the first region 106.

The terminal part 116 arranged in the second region 107 is arranged along a first side of the base film 102. The first drive circuit 110 arranged in the second region 107 is arranged adjacent to the terminal part 116. A signal for driving the display device 100 is input to the terminal part 116. Based on the input signal, the first drive circuit 110 outputs a video signal to a pixel 109. In the third region 108 is arranged with a plurality of wirings which connect the first drive circuit 110 and the pixels 109, and a plurality of wirings which connect a first drive circuit, and the terminal part 116 and the second drive circuit 112.

A first film 104 is arranged on the first surface of the base film 102. The first film 104 is arranged so as to cover the first region 106. In the present embodiment, the display device 100 is configured so that an image displayed in the first region 106 is visually recognize through the first film 104. The first film 104 is an optical film such as a retardation film, a polarizing film, an antireflection film, or a transparent film which does not have optical anisotropy. The first film 104 has a structure in which one or several of these functional films are combined. The first film 104 included of these functional films improves a visibility of an image displayed in the first region 106. In addition, the first film 104 is also used as a member for protecting the first region 106.

The first side of the first film 104 is arranged along a third side of the first region 106 (one side which intersects a first side and a second side along the second drive circuit 112). The first side of the first film 104 is arranged further to the inside than the second region 107 where the first drive circuit 110 and the terminal part 116 are arranged. Therefore, the second region 107 and the third region 108 are exposed from the first film 104. The second region 107 and the third region 108 are not regions for displaying images directly and need not absolutely necessary be covered with the first film 104.

Since the base film 102 has a film shape and has flexibility, it can be fold or bent. The base film 102 is manufactured using an organic material. For example, the base film 102 is manufactured from a polymer material (polyimide) including an imide bond at a repeating unit, or a polymer material (polyamide) obtained by bonding a several monomers using an amide bond. The display device 100 according to the present embodiment can be fold or bent because the base film 102 has flexibility.

In the present embodiment, the display device 100 is arranged at a position where the third region 108 overlaps a folding region 118. A line X1-X2 shown in FIG. 1 indicates a folded part of the folding region 118. By folding the base film 102 to a second surface side opposite to the first surface in the third region 108, the second region 107 is arranged on the rear surface side of the first region 106. That is, the first drive circuit 110 and the terminal part 116 are arranged on the rear surface side of the display region 113 where the pixels 109 are arranged. In the display panel, a region outside the first region 106 is called a periphery region or a frame region. According to the present embodiment, by allowing the base film 102 to be folded in the third region 108, the second region 107 is hidden by the rear surface of the first region 106 and thereby it is possible to realize a substantially narrow frame.

In order to achieve a narrow frame of the display panel, it is preferred that the folded part along the line X1-X2 is brought closer to the first region 106 side, in other words, closer to the first film 104 side. Ideally, it is preferred that to be folded along one side of the first film 104 adjacent to the third region 108 (or overlapping with the third region 108).

If the base film 102 can be folded in this way, it is possible to ensure that the frame region including the second region 107 and the third region 108 is not exposed in a planar view of the display panel.

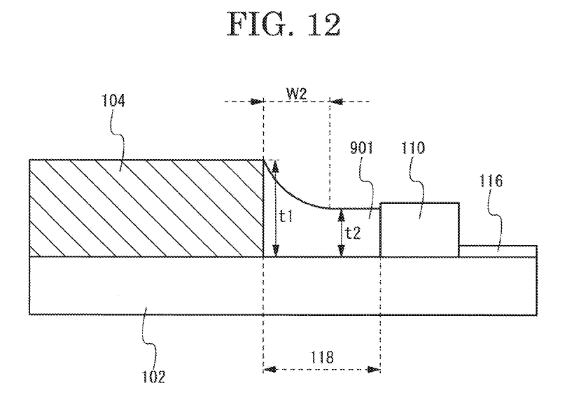

As is shown in FIG. 12, although the third region 108 is exposed from the first film 104, a resin layer 901 is arranged in order to protect the surface. However, when the resin layer 901 and an end surface of the first film 104 are in contact, the resin crawls up on the end face of the first film 104 due to surface tension of the resin during manufacturing. Therefore, the resin layer 901 is formed with a thickened region across a predetermined distance W2 from the end surface of the first film 104. For example, the resin layer 901 has a film thickness t1 at the end surface of the first film 104 and becomes thicker compared to a film thickness t2 of other regions. For example, the film thickness t1 of the resin layer 901 has the same thickness as the film thickness of the first film 104. Although the thickness of the resin layer 901 decreases from the film thickness t1 as it separates from the end surface of the first film 104, a predetermined width W2 is necessary until substantially matches the film thickness t2 of a flat region.

For example, in the case where the thickness of the first film 104 is 90 μm, the designed film thickness t2 of the resin layer 901 is 70 μm, and the width of the folded region 118 in the third region 108 is 2 mm from the end surface of the first film 104, then the film thickness t1 of the end surface of the first film 104 is 90 μm and the width W2 of the thickened region becomes 50 μm or more. In this case, when the base film 102 is folded, it is difficult to fold the base film 102 near the end part of the first film 104 due to the influence of the thick film part of the resin layer 901.

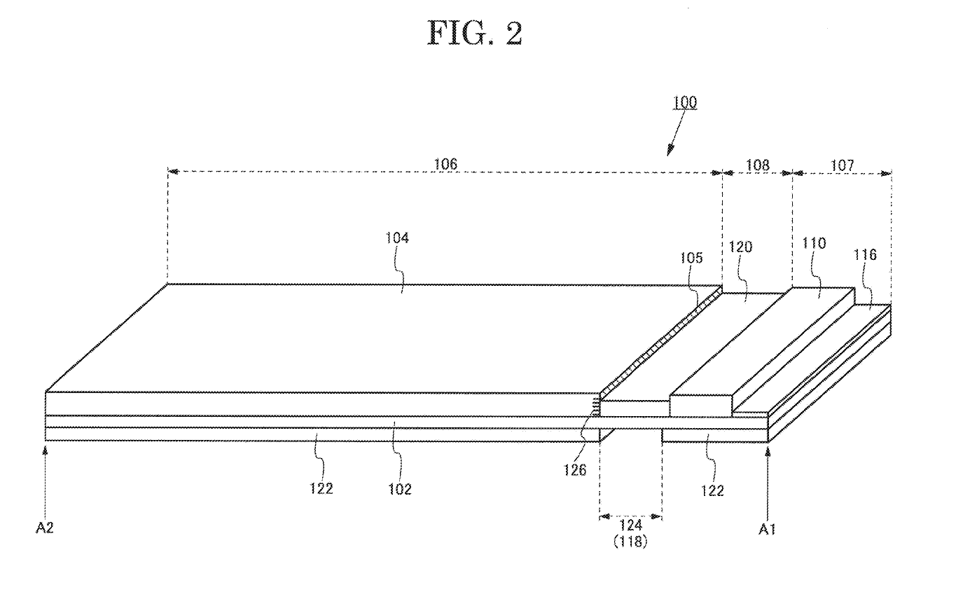

FIG. 2 is a perspective diagram showing the display device 100 according to one embodiment of the present invention. The perspective diagram shown in FIG. 2 shows a structure corresponding to the line A1-A2 shown in FIG. 1. In the display device 100, the first film 104 is arranged in the first region 106, and the first drive circuit 110 and the terminal part 116 are arranged in the second region 107. The third region 108 is arranged with a plurality of wirings above the base film 102, and a resin layer 120 is arranged to cover the plurality of wirings. The resin layer 120 is cured by applying a resin composition and performing heat treatment or light irradiation. The resin layer 120 is arranged in contact with an end surface 105 of the first film 104. The end surface 105 of the first film 104 is roughened.

Since the end surface 105 of the first film 104 is roughened, it is possible to prevent the resin film from rising due to the influence of surface tension when the resin composition is applied. For example, the roughened state of the end surface 105 of the first film 104 may have a groove, a step, or the surface may be satin finished. FIG. 2 shows a form in which a plurality of grooves 126 is arranged on the end surface 105 of the first film 104 as one example.

A second film 122 may be arranged on the second surface side of the base film 102. The second film 122 is arranged with an opening part 124 in a region corresponding to the folding region 118 of the base film 102, and the second film 122 is arranged to cover substantially the entire surface of the other regions. The second film 122 is arranged in close contact with the base film 102 via an adhesive layer (not shown in FIG. 2).

In the base film 102, a rigidity of a region where the second film 122 is arranged has higher than that of the opening part. As a result, it is possible to define a region corresponding to the opening part 124 arranged in the second film 122 as the folding region 118 of the base film 102. That is, since the region which overlaps the opening part 124 of the second film 122 in the base film 102 bends more easily than other regions, it is possible to use this region as the folding region 118. The opening part 124 of the second film 122 can be arranged, for example, in a region which overlaps with the third region 108 of the display device 100. In this way, the third region 108 can be used as the folding region 118 of the display device 100. Since the second film 122 supports the base film 102, it has the function of a support film.

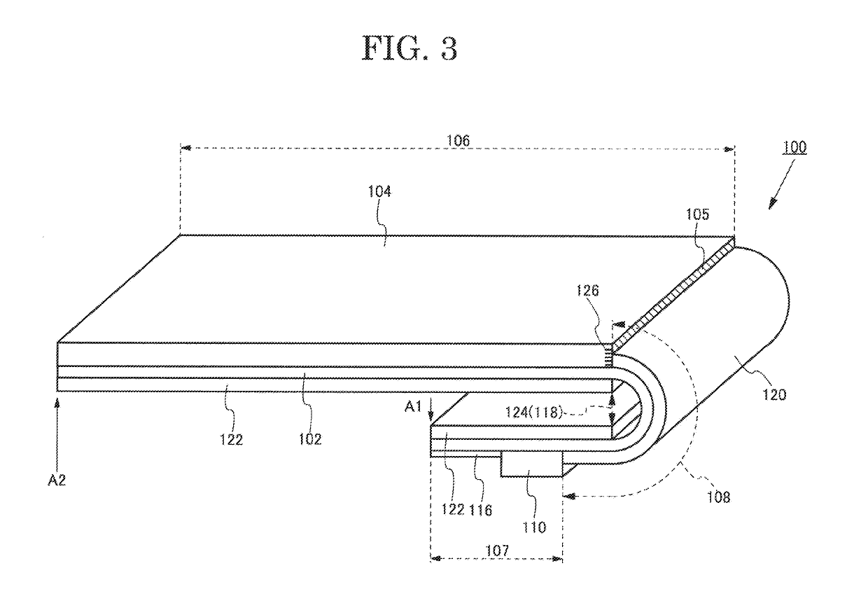

FIG. 3 shows a state in which a part of the display device 100 is folded. Specifically, FIG. 3 shows a state in which the base film 102 is folded in a region corresponding to the third region 108. As is shown in FIG. 3, the base film 102 is folded and the second region 107 is arranged on the rear surface of the region where the first film 104 is arranged. By folding the base film 102, the resin layer 120 which is arranged on the base film 102 is also bent. In this case, bending stress acts on the base film 102, the resin layer 120, and a wiring layer (not shown in FIG. 3) between the base film 102 and the resin layer 120.

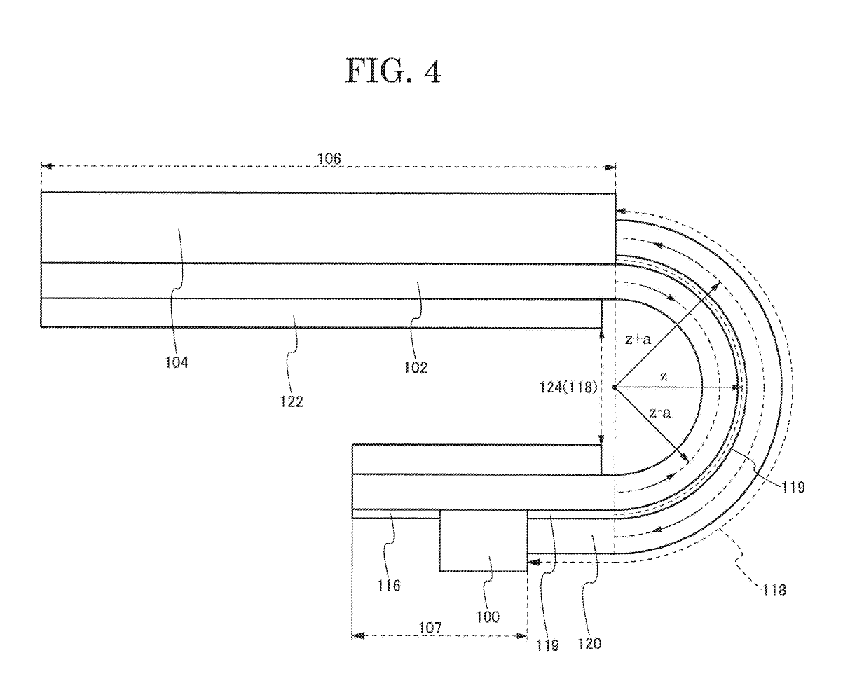

As is shown in FIG. 4, bending stress which acts when the base film 102 is bent does not uniformly act on each layer, but a compressive stress acts in a region (z−a) having a smaller curvature radius than a certain curvature radius z as a boundary, and a tensile stress acts in a region (z+a) having a large of curvature radius. In addition, at the curvature radius z, it becomes a neutral plane where compressive stress or tensile stress not acts. From the viewpoint of preventing wire breakage, it is preferable that a wiring 119 arranged in the third region 108 is located in a neutral plane or close to a neutral plane which stress dos not act (it does not extend or constrict). The position of the neutral plane changes according to the thickness of each layer.

For example, as is shown in FIG. 4, the film thickness of each layer of the base film 102, the wiring 119 and the resin layer 120 is set so that the neutral plane is located on the wiring 119. However, as is shown in FIG. 12, when the film thickness of the resin layer 901 is not uniform, the position of the neutral plane becomes misaligned. On the other hand, since the end surface 105 of the first film 104 is roughened, as is shown in FIG. 3, crawling up of the resin layer 120 is suppressed and it is possible to make film thickness uniform. By arranging the plurality of grooves 126 on the end surface 105 of the first film 104, the film thickness of the resin layer 120 can be made uniform, and the folded region 118 can be brought close to the first film 104 when the base film 102 is folded. In this way, the width of the folded region 118 of the base film 102 can be narrowed and it is possible to bring the folded region 118 close to the first film 104.

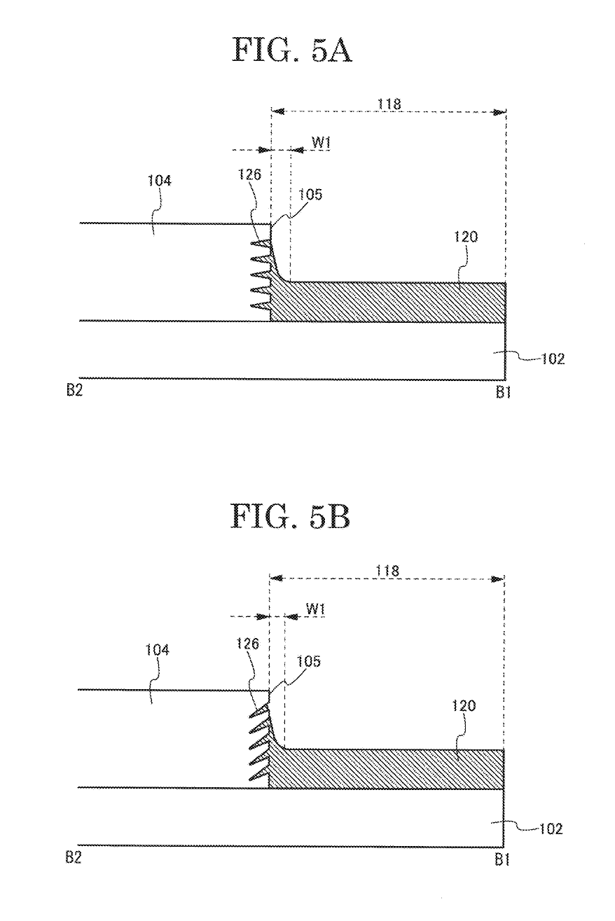

The structure of the first film 104 is explained while referring to FIG. 5A and FIG. 5B. FIG. 5A and FIG. 5B show a cross-sectional structure corresponding to the line B1-B2 shown in FIG. 1. Specifically, FIG. 5A and FIG. 5B show the arrangement of the base film 102, the first film 104, the third region 108 and the resin layer 120. The plurality of grooves 126 is arranged on the end surface 105 of the first film 104. It is preferred that the plurality of grooves 126 are arranged on the end surface 105 of the first film 104. For example, as is shown in FIG. 5A and FIG. 5B, it is preferred that the plurality of grooves 126 is arranged in the thickness direction of the first film 104.

FIG. 5A shows a form in which the groove 126 arranged on the end surface 105 of the first film 104 is arranged substantially parallel to the first surface of the base film 102. In other words, the plurality of grooves 126 is recessed substantially parallel to the first surface of the base film 102 from the end surface 105 in the direction of a pixel 109. The resin layer 120 contacts the end surface 105 of the first film 104 and is further arranged to fill the plurality of grooves 126. The resin layer 120 is arranged thinner than the thickness of the first film 104. The plurality of grooves 126 having a width of 5 μm to 30 μm, a depth of 5 μm or more, preferably a depth of 10 μm or more is arranged on the end surface 105 of the first film 104.

By arranging this type of the plurality of grooves 126, it is possible to suppress the resin layer 120 from being filled in the plurality of grooves 126, and the resin is suppressed from crawling up on the end surface 105 of the first film 104. In this way, in the vicinity of the first film 104, it is possible to reduce the width W1 of a region where the film thickness of the resin layer 120 increases. That is, by arranging the plurality of grooves 126 on the end surface 105 of the first film 104, it is possible to reduce the width W1 of the thickened region compared to the width W2 (width W2 exemplified in FIG. 12) when a groove is not arranged (W2<W1). In addition, it is possible to ensure that the resin layer 120 does not reach the end part (upper end part) of the end surface 105 on the side opposite to the base film 102.

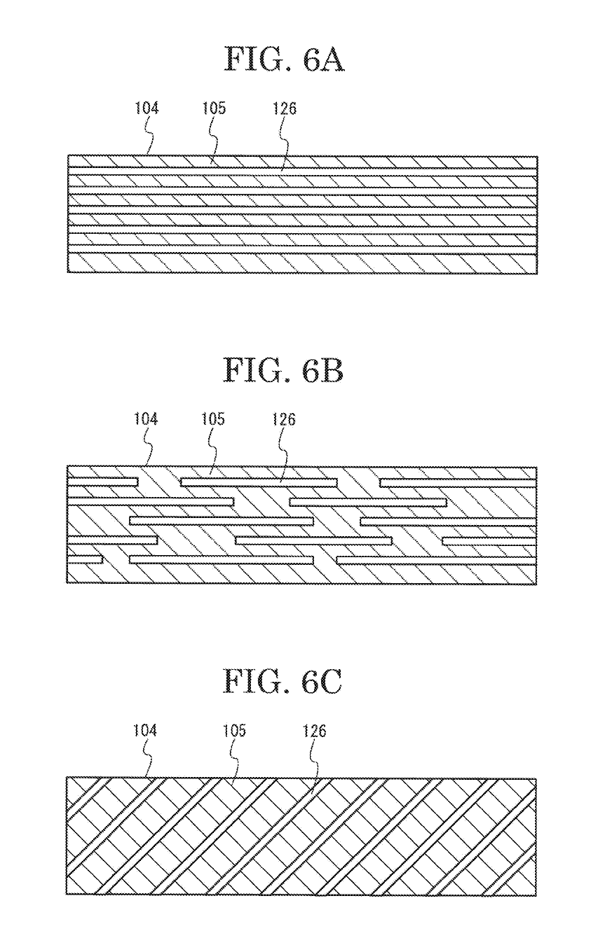

FIG. 6A, FIG. 6B and FIG. 6C schematically show a structure when the end surface 105 of the first film 104 is viewed from the front. FIG. 6A shows a form in which the plurality of grooves 126 is arranged substantially parallel to the upper surface of the first film 104. In other words, the plurality of grooves 126 is arranged with an opening part at the end surface 105, and the opening part extends substantially parallel to the main surface of the first film 104. The plurality of grooves 126 is arranged continuously from one end (first end part) of the end surface 105 of the first film 104 to the other end (second end part) opposite to the first end. The plurality of grooves 126 are arranged at predetermined intervals with respect to the thickness direction of the first film 104.

FIG. 6B shows a form in which the plurality of grooves 126 extending substantially parallel to the upper surface of the first film 104 is arranged discontinuously. In addition, FIG. 6C shows a form in which the plurality of grooves 126 is arranged in a diagonal direction with respect to the upper surface of the first film 104. In other words, the plurality of groove 126 is arranged with an opening part at the end surface 105, and the opening part extends in a diagonal direction with respect to the main face of the first film 104. The plurality of grooves 126 arranged in a diagonal direction are arranged on the end surface 105 of the first film 104. In this way, by arranging the plurality of grooves 126 on the end surface 105 of the first film 104, even if the resin layer 120 is arranged with a thickness equal to or less than the thickness of the first film 104, it is possible to prevent the resin being absorbed in the groove 126 and prevent the resin layer 120 from crawling up.

Furthermore, FIG. 6A, FIG. 6B, and FIG. 6C are merely examples, and the form of the groove 126 is not limited to the form shown in the diagrams. For example, a groove 126 in a horizontal direction shown in FIG. 6A and FIG. 6B and a groove 126 in a diagonal rear direction shown in FIG. 6C may be combined, or the groove 126 may be randomly arranged.

In addition, as is shown in FIG. 5B, the plurality of grooves 126 arranged on the end surface 105 of the first film 104 is arranged in a diagonal direction with respect to the first surface of the base film 102. In other words, the plurality of grooves 126 is arranged so as to be deep in a diagonal direction with respect to the end surface 105 in a cross-sectional view of the first film 104. It is also possible to say that the plurality of grooves 126 is recessed in a diagonal direction with respect to the first surface of the base film 102 from the end surface 105 in the direction of a pixel 109. That is, the plurality of grooves 126 shown in FIG. 5B is located at a position where the position of the bottom part of the groove is lower than the opening end with respect to the thickness direction of the first film 104. By arranging the plurality of grooves 126 in which the depth is distributed in a diagonal direction on the end surface 105 of the first film 104, the resin can easily flow into the plurality of grooves 126. In this way, at the end face 105 of the first film 104, the resin layer 120 reaches the upper end of the end surface 105 and it is possible to suppress the width of the thickened region from widening.

It is possible to form the plurality of grooves 126 arranged on the end surface 105 of the first film 104 by laser processing. In addition, it is possible to form the plurality of grooves 126 on the end surface 105 by grinding. Furthermore, although the form is different to the groove, the end surface 105 of the first film 104 may also be sandblasted to form a satin like rough surface.

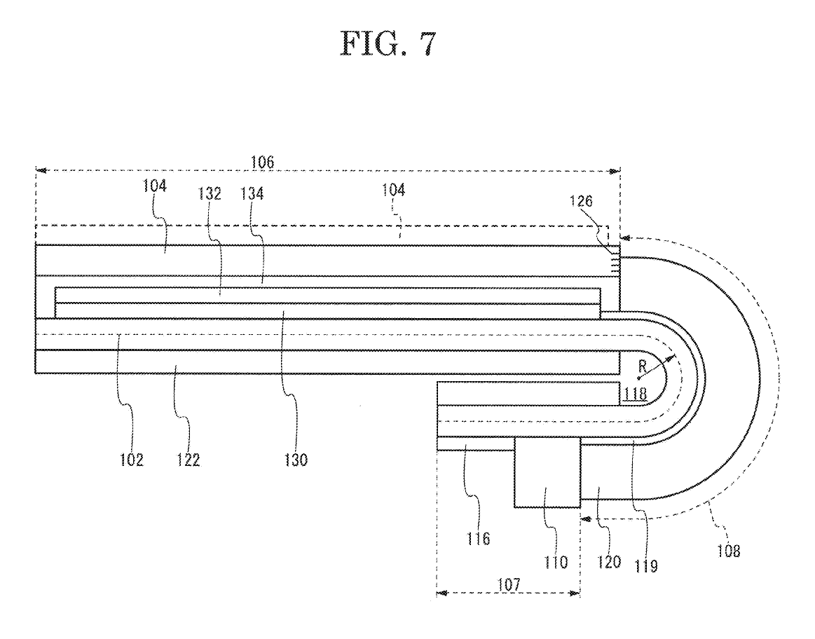

FIG. 7 is a cross-sectional diagram showing a simplified stacked layer structure of the display device 100 according to one embodiment of the present invention. A drive element layer 130 and a display element layer 132 are stacked on the first surface of the base film 102. The first region 106 and the second drive circuit 112 are formed by the drive element layer 130 and the display element layer 132. The upper surface and the side surface of the display element layer 132 are covered by a sealing layer 134. The display element layer 132 is arranged sandwiched between a lower drive element layer 130 and an upper layer side sealing layer 134. The first film 104 is arranged on the upper layer side of the sealing layer 134.

The display element layer 132 includes a plurality of display elements. For example, a light emitting element is used as the display element. An organic electroluminescent element (also referred to as “organic EL element” below) in which a light emitting layer is formed with an organic electroluminescent material (also referred to as “organic EL material” below) is suitably used as the light emitting element. In addition, the display element layer 132 may also be formed by using a liquid crystal element in which a liquid crystal layer is arranged between a pair of electrodes, or an electrophoretic element in which a fluid of particles having polar is controlled by the action of an electric field instead of the light emitting element.

In the drive element layer 130, a pixel circuit and a drive circuit are formed by an active element such as a transistor, and a passive element such as a capacitor and a resistor. In the drive element layer 130, an insulating layer, a semiconductor layer and a conductive layer are appropriately stacked in order to form these circuits. A transistor of the drive element layer 130 and the display element of the display element layer 132 are electrically connected.

The sealing layer 134 is arranged in order to protect the display element layer 132 from water vapor contained in the air. The sealing layer 134 includes an inorganic insulation film which has low water vapor permeability in order to block water vapor. For example, the sealing layer 134 is arranged in a structure in which the upper layer side and lower layer side of the organic insulating film are sandwiched by inorganic insulating films having low water vapor permeability.

The first film 104 is formed from a functional film such as a phase difference film, a polarizing film, an antireflection film or a transparent film which does not have optical anisotropy. The first film 104 may be formed by combining one or more of these functional films. In the first film 104, a transparent film which does not have optical anisotropy and a polarizing film 170 may also be stacked from the sealing layer 134 side. The first film 104 may further be formed by stacking an antireflection film on the polarizing film. In the present embodiment, the resin layer 120 does not protrude beyond the end surface 105 of the first film 104, thereby it is possible to arrange the polarizing film 170 or the like in close contact with the first film 104.

The first drive circuit 110 and the terminal part 116 are provided in the second region 107 on the first surface of the base film 102. The first drive circuit 110 and the terminal part 116 are arranged outside the sealing layer 134. The first drive circuit 110 is connected by the wiring(s) 119 which extends from the drive element layer 130. The third region 108 arranged with the wiring(s) 119 is a region which is not covered by the sealing layer 134. Instead, the wiring(s) 119 is covered by the resin layer 120. The resin layer 120 is arranged to cover substantially the entire surface of the third region 108.

The display device 100 according to the present embodiment has the folding region 118 on the base film 102. The folding region 118 is set in the third region 108. When the thickness of the base film 102 is 10 μm to 50 μm, the curvature radius of the folding region 118 can be, for example, 0.1 mm to 10 mm, preferably 0.5 mm to 5 mm. Furthermore, it is not necessary that the curvature radius of the folding region 118 is constant at a part where the base film 102 is bent, and the curvature radius may continuously change. In addition, the angle (bending angle) at which the base film 102 is bent can be set within a range of 0 to 180 degrees.

The second film 122 may be arranged on the second surface side of the base film 102. By arranging the second film 122, it is possible to increase the rigidity of the base film 102. In addition, by arranging an opening part or a notch part in a part of the second film, it is possible to reduce the rigidity of the base film 102 at that part. As is described above, by arranging the opening part 124 in the second film 122 in alignment with the third region 108, that part may be defined as the folding part in the display device 100.

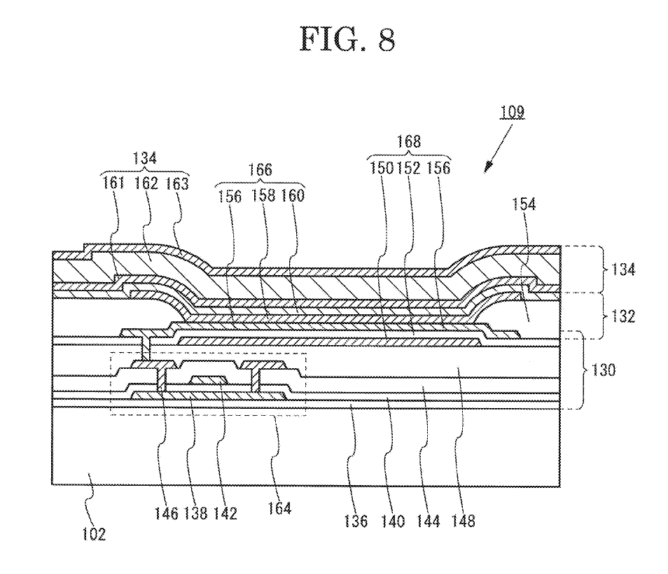

FIG. 8 shows a cross-sectional structure of the pixel 109 in the display device 100. The pixel 109 includes at least one transistor 164, a light emitting element 166 and a capacitor 168. The transistor 164, the light emitting element 166 and the capacitor 168 are electrically connected. A current (drain current) which flows between a source and drain is controlled by a voltage applied to the gate of the transistor 164. The light emission intensity of the light emitting element 166 is controlled by the drain current. The capacitor 168 is connected between the gate and the source of the transistor 164, thereby a gate voltage is applied and the capacitor 168 is arranged to maintain the gate voltage constant.

In FIG. 8, the drive element layer 130 includes a first insulating layer, a semiconductor layer 138, a second insulating layer 140, a gate electrode 142, a third insulating layer 144, a source/drain electrode 146, a fourth insulating layer 148, a capacitor electrode 150, a fifth insulating layer 152 and a first electrode 156. The display element layer 132 includes a first electrode 156, a sixth insulating layer 154, an organic layer 158 and a second electrode 160. In addition, the sealing layer 134 includes a first inorganic insulating film 161, an organic resin film 162 and a second inorganic insulating film 163.

In the drive element layer 130, the transistor 164 has a structure in which the semiconductor layer 138, the second insulating layer 140 (gate insulating layer) and the gate electrode 142 arranged above the first insulating layer 136 are stacked. The semiconductor layer 138 is manufactured from a semiconductor material such as amorphous silicon or polycrystalline silicon or a metal oxide. The semiconductor layer 138 is insulated from the gate electrode 142 by the second insulating layer 140. The third insulating layer 144 is arranged on the upper layer side of the gate electrode 142. The source/drain electrode 146 is arranged on the upper layer side of the third insulating layer 144. The source/drain electrode 146 contacts the semiconductor layer 138 via a contact hole which is formed in the third insulating layer 144. The first insulating layer 136 and the second insulating layer 140 are manufactured using an inorganic insulating material such as silicon oxide, silicon nitride or silicon oxynitride. In addition, the gate electrode 142 and the source/drain electrode 146 are manufactured using a metal material such as aluminum, molybdenum, titanium or tungsten and the like.

The fourth insulating layer 148 is arranged above the source/drain electrode 146. The fourth insulating layer 148 is used as a planarizing film which buries irregular surfaces of the semiconductor layer 138, the gate electrode 142 and the source/drain electrode 146 and the like, and flattens the surface. The fourth insulating layer 148 is manufactured from an organic insulating material such as polyimide or acrylic.

The capacitor electrode 150 is arranged on the upper surface of the fourth insulating layer 148 and the fifth insulating layer 152 is further manufactured. Furthermore, the first electrode 156 is arranged on the upper surface of the fifth insulating layer 152. The first electrode 156 is electrically connected to the source/drain electrode 146 via a contact hole which passes through the fifth insulating layer 152 and the fourth insulating layer 148. The first electrode 156 is arranged to overlap the capacitor electrode 150 interposed by the fifth insulating layer 152. The capacitor 168 is manufactured in a region where the capacitor electrode 150, the fifth insulating layer 152, and the first electrode 156 overlap. The fifth insulating layer 152 which is used as a dielectric film of the capacitor 168 is manufactured from an inorganic insulating material such as silicon nitride, silicon oxide, or silicon nitride oxide and the like.

The display element layer 132 is arranged substantially on an upper layer of the fifth insulating layer 152. The sixth insulating layer 154 which covers a periphery part of the first electrode 156 and exposes an inner region is arranged above the fifth insulating layer 152. The organic layer 158 is arranged to cover the surface of the sixth insulating layer 154 from the upper surface of the first electrode 156. The second electrode 160 is arranged to cover the upper surfaces of the organic layer 158 and the sixth insulating layer 154. The light emitting element 166 is manufactured from a first electrode 156, an organic layer 158 and a second electrode 160. In the light emitting element 166, a region where the first electrode 156, the organic layer 158 and the second electrode 160 overlap serves as a light emitting region. The sixth insulating layer is manufactured from an organic resin material in order to form a smooth step at the opening end where the first electrode 156 is exposed. An acrylic resin, a polyimide resin and a polyamide resin or the like is used as the organic resin material.

The organic layer 158 is manufactured using a low molecular or high molecular organic EL material. In the case where a low molecular organic electroluminescent material is used, in addition to a light emitting layer including an organic EL material, the organic layer 158 is appropriately arranged with a carrier injection layer (hole injection layer, electron injection layer) and a carrier transport layer (hole injection layer, electron injection layer) which sandwich the light emitting layer. For example, the organic layer 158 has a structure in which a light emitting layer is sandwiched between a hole injection layer and an electron injection layer. Furthermore, in addition to the hole injection layer and the electron injection layer, the organic layer 158 is appropriately added with a hole transport layer, an electron transport layer, a hole blocking layer and an electron blocking layer and the like.

In the present embodiment, it is assumed that the light emitting element 166 is a so called top emission type which radiates light emitted from the organic layer 158 to the second electrode 160 side. The first electrode 156 is a metal film or manufactured including a metal film so as to reflect light emitted from the organic layer 158. For example, the first electrode 156 is preferred to be manufactured including a metal film having high light reflectance in the visible light band such as aluminum (Al) or silver (Ag) and the like. In addition, the first electrode 156 may be manufactured by stacking a transparent conductive film and a metal film such as indium tin oxide (also referred to as “ITO” below), indium zinc oxide (also referred to as “IZO” below), zinc oxide to added with aluminum (also referred to as “AZO” below) and zinc oxide added with gallium (also referred to as “GZO” below). The second electrode 160 is manufactured from transparent conductive film such as ITO, IZO, AZO and GZO or the like since it allows light emitted from the organic layer 158 to pass through. The second electrode 160 is arranged over substantially the entire surface of the first region 106.

The sealing layer 134 is arranged on the upper surface of the second electrode 160. The sealing layer 134 is formed from an inorganic insulating film. In addition, as is shown in FIG. 8, the sealing layer 134 may also be included the first inorganic insulating film 161, the organic resin film 162 and the second inorganic insulating film 163. An inorganic insulating material such as a silicon nitride film or an aluminum oxide film is used as the first inorganic insulating film 161 and the second inorganic insulating film 163. An acrylic resin, a polyimide resin, a polyamide resin and an epoxy resin and the like is used as the organic resin film.

In the structure of the pixel 109 shown in FIG. 8, the drive element layer 130 has a thickness of approximately 2 μm to 5 μm, the display element layer 132 has a thickness of approximately 1 μm to 3 μm, and the sealing layer 134 has a thickness of approximately 10 μm to 20 μm.

Furthermore, although not shown in FIG. 8, the first film 104 is arranged on the upper layer side of the sealing layer 134.

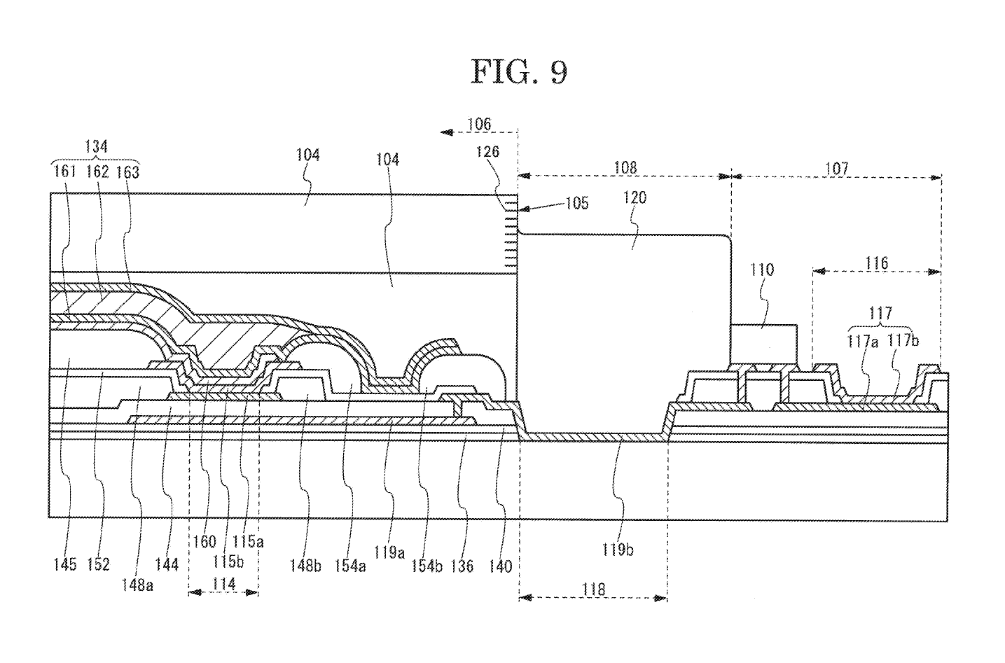

A cross-sectional structure of the display device 100 corresponding to the line C1-C2 shown in FIG. 1 is shown in FIG. 9. That is, FIG. 9 shows a cross-sectional of the periphery of the common contact 114 in the second region 107, the third region 108 and the first region 106 in the display device 100.

The common contact 114 which is arranged in the first region 106 is a part where the second electrode 160 which extends from the pixel 109 is connected with a common wiring 115. The common wiring 115 may be formed by a first common wiring 115a which is arranged on the third insulating layer 144 and a second common wiring 115b interposed between second electrodes 160. It is possible to form the first common wiring 115a from a conductive layer the same as the conductive layer which forms the source/drain electrode 146, and it is possible to form the second common wiring 115b from a conductive layer the same as the first electrode 156 of the light emitting element 166.

Furthermore, in the common contact 114, the fourth insulating layer 148 and the sixth insulating layer 154 which are formed from an organic material are removed, and an opening part is arranged to expose the first common wiring 115a. In addition, the fifth insulating layer 152 is arranged to cover the upper surface and the side surface of the fourth insulating layer 148. The common contact 114 has a structure in which the third insulating layer 144 which is formed from an inorganic material, the first common wiring 115a, the second common wiring 115b, the second electrode 160 and the first inorganic insulating film 161 are stacked. By this structure, it is possible to prevent water vapor from entering the fourth insulating layer 148.

The sixth insulating layer 154 (sixth insulating layers 154a, 154b) has a region which is divided into two above the fifth insulating layer 152 on the outer side of the common contact 114, that is, on the third region 108 side. In this region, the first inorganic insulating film 161 and the second inorganic insulating film 163 are arranged in contact with each other and are arranged along the surfaces of the sixth insulating layer 154a, the fifth insulating layer 152 and the sixth insulating layer 154b. An end part of the resin layer 120 is arranged on the sixth insulating layer 154a or in a region which does not exceed the sixth insulating layer 154a. Therefore, the first inorganic insulating film 161 and the second inorganic insulating film 163 are arranged in close contact in the region further in front than the end part of the organic resin film 162. By providing such a structure, it is possible to prevent the organic resin film 162 which forms the sealing layer 134 from being exposed to the exterior. In addition, by arranging the region where the sixth insulating layer 154 is divided, it is possible to ensure that the organic resin film 162 does not reach the end parts of the first inorganic insulating film 161 and the second inorganic insulating film 163.

The first region 106 is arranged with the first film 104 via the sealing resin 155. The end surface 105 of the first film 104 is roughened. In addition, the end surface 105 of the first film 104 matches the end of the sixth insulating layer 154b or is arranged further to the outside of the sixth insulating layer 154b. By arranging the first film 104 up to the end part of the sixth insulating layer 154b so as to cover it, it is possible to reliably protect the first region 106.

In the first region 106, wiring(s) 119a is arranged between the second insulating layer 140 and the third insulating layer 144. Furthermore, wiring(s) 119b arranged on the upper layer side of the third insulating layer 144 extends to the third region 108. The third region 108 includes a region which overlaps the folding region 118. In the folding region 118, the first insulating layer 136, the second insulating layer 140, the third insulating layer 144 and the fifth insulating layer 152 which are formed from an inorganic insulating material on the base film 102 are removed. In other words, the first insulating layer 136, the second insulating layer 140 and the third insulating layer 144 which are arranged on the lower layer side of the wiring(s) 119b which extends from the first region 106 are removed in the folding region 118, and the wiring(s) 119b is arranged on the first surface of the base film 102.

The third region 108 is arranged with a resin layer 120 which buries the wiring(s) 119b. The resin layer 120 is arranged as a protective member of the wiring(s) 119b. The resin layer 120 is arranged to contact the end part of the first film 104 in order to securely protect the wiring(s) 119b. Although the resin layer 120 is arranged on the base film 102, it is arranged with a thickness which does not exceed the height of the first film 104.

The first film 104 has a thickness of 50 μm to 200 μm, preferably 80 μm to 120 μm, for example 90 μm. As described above, since the total thickness of the drive element layer 130 and the sealing layer 134 in the first region 106 does not exceed 30 μm, by setting the thickness of the resin layer 120 to 50 μm to 100 μm, for example 70 μm, it is possible to ensure that the height of the film 104 is not exceeded.

The end part of the resin layer 120 is arranged in contact with the end surface 105 of the first film 104. In this case, since the end surface 105 of the first film 104 is roughened, even if a resin composition is applied, the influence of surface tension can be reduced, and it is possible to suppress crawling up at the end surface 105. In other words, it is possible to make the thickness of the resin layer 120 uniform. In this way, it is possible to reduce the width of the folding region 118. It is possible to set the width of the folding region 118 to be 1 mm to 5 mm, for example 2 mm.

Furthermore, an acrylic resin, a polyimide resin, a polyamide resin, an epoxy resin and a urethane resin and the like can be used as the resin layer 120.

In the terminal part 116, the first insulating layer 136, the second insulating layer 140 and the third insulating layer 144 are stacked on the first surface of the base film 102, and a terminal electrode 117 is formed by a first terminal electrode layer 121a and second terminal electrode layer 121b arranged thereupon. For example, the first terminal electrode layer 121a is formed from the same conductive layer as the conductive layer which forms the source/drain electrode 146 which is arranged in the pixel 109, and the second terminal electrode 121b is formed from the same conductive layer as the first electrode 156 of the light emitting element 166.

As described above, according to the present embodiment, when the base film 102 is folded, it is possible to make the film thickness of the resin layer 120 arranged in the folding region 118 uniform. In this way, it is possible to arrange the folding region 118 close to the first region 106, and it is possible to realize a narrow frame of the display device. In the present embodiment, a configuration in which a plurality of grooves 126 are provided on the end surface 105 of the first film 104 is shown, a similar advantageous effect can be obtained if at least one groove 126 is provided on the end surface 105.

### Second Embodiment

The present embodiment exemplifies a form in which the shape of the end surface 105 of the first film 104 is different from that shown in FIG. 5A and FIG. 5B in the first embodiment.

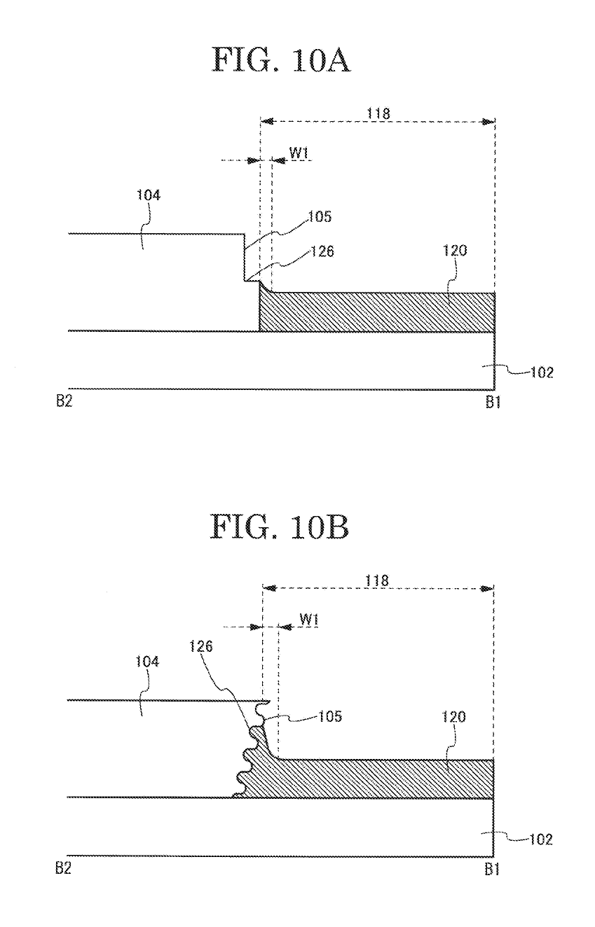

FIG. 10A shows a form in which a step part 128 is arranged on the end surface 105 of the first film 104. In this way, by arranging the step part 128 on the end surface 105 of the first film 104, it is possible to reduce the height of the end face in contact with the resin layer 120. In other words, the thickness of the first film 104 at the end surface 105 has a first thickness and a second thickness larger than the first thickness, a part of the first thickness part, that is, a part where the thickness is small, is located further to the side of the third region 108 than a part of the second thickness. In this way, it is possible to suppress crawling up of the resin layer 120. Furthermore, although FIG. 10A shows that there is one step on the end surface 105 of the first film 104, the present embodiment is not limited to this form. A plurality of steps may also be arranged on the end surface 105 of the first film 104. That is, the stepped part 128 may be a multi-step. By making the step of the end surface of the first film 104 multi-step, it is possible to more securely suppress crawling up of the resin layer 120. In other words, it is possible to suppress thickening at the end of the resin layer 120.

FIG. 10B shows a form in which the end surface 105 of the first film 104 is moldered in a taper shape. The taper shape of the end surface 105 is a so-called reverse tapered type, in which the upper end part is located on the outer side with respect to the end part in contact with the base film 102. The resin layer 120 contacts with such this reverse taper shaped end surface 105, thereby crawling up at the end part is suppressed. In addition, as is shown in FIG. 10B, by arranging the plurality of grooves 126 on the reverse taper shaped end surface 105, it is possible to more securely suppress crawling up of the resin layer 120. In other words, it is possible to suppress thickening at the end part of the resin layer 120.

The structure shown in the present embodiment can be implemented by appropriate combination with the first embodiment.

### Third Embodiment

The present embodiment exemplifies examples of the form of the end surface 105 of the first film 104 which are different from those of the first embodiment and the second embodiment.

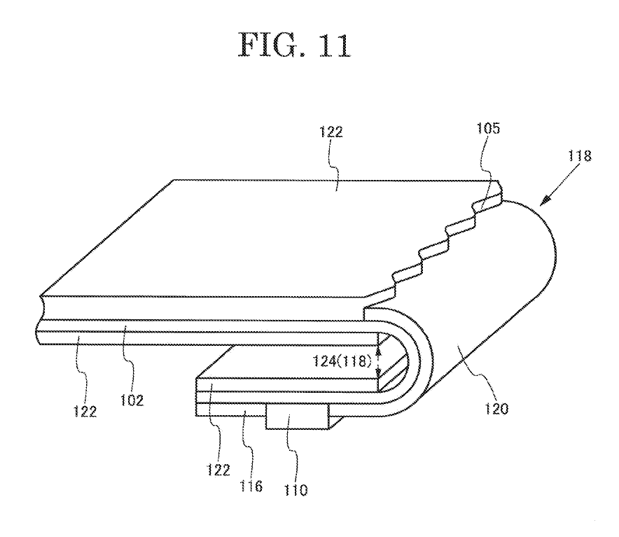

FIG. 11 is a perspective diagram of the display device 100 and shows an aspect in which the end surface 105 of the first film 104 is bent in a wave shape. By making the end surface 105 of the first film 104 in a wave shape, the area in contact with the resin layer 120 increases. In this way, it is possible to suppress an increase in the thickness of the region where the resin layer 120 contacts the end surface 105. In the form shown in FIG. 11, the plurality of grooves 126 may be arranged on the end surface 105 of the first film 104, or a step part 128 may be arranged. In this way, by shaping the end surface 105 of the first film 104 into the wave shape, it is possible to suppress crawling up of the resin layer 120. In other words, it is possible to suppress thickening at the end part of the resin layer 120.

The structure shown by the present embodiment can be realized be appropriately combining the first embodiment and the second embodiment.

What is claimed is:

1. A display device comprising:
a base plate including a first region, a second region and a third region;
a first film covering the first region; and
a resin layer covering the third region,
wherein
the base plate includes a first surface and a second surface opposite to the first surface,
the first region is located on the first surface and is arranged with a plurality of pixels,
the second region is located on the second surface and is arranged with a terminal part,
the third region is located on the first surface and between the first region and the second region, and
an end surface facing the third region of the first film is roughened and the resin layer contacts the end surface.

2. The display device according to claim 1, wherein the first film includes at least one groove on the end surface.

3. The display device according to claim 2, wherein the at least one groove recesses roughly parallel to the first surface towards a direction of the plurality of pixels from the end surface.

4. The display device according to claim 2, wherein the at least one groove recesses in a diagonal direction with respect to the first surface towards a direction of the plurality of pixels from the end surface.

5. The display device according to claim 2, wherein the at least one groove is arranged with an opening part at the end surface, and the opening part extends substantially parallel to a main surface of the first film.

6. The display device according to claim 2, wherein the at least one groove is arranged with an opening part at the end surface, and the opening part extends in a diagonal direction to a main surface of the first film.

7. The display device according to claim 2, wherein the end surface includes a first end part and a second end part facing the first end part, and the at least one groove extends continuously from the first end part to the second end part.

8. The display device according to claim 2, wherein the end surface includes a first end part and a second end part facing the first end part, and the at least one groove extends discontinuously from the first end part to the second end part.

9. The display device according to claim 2, wherein the at least one groove comprises a plurality of grooves.

10. The display device according to claim 9, wherein the plurality of grooves is arranged in a thickness direction of the first film.

11. The display device according to claim 2, wherein the at least one groove has a depth of 5 μm or more.

12. The display device according to claim 1, wherein the first film has a step on the first surface.

13. The display device according to claim 12, wherein a thickness of the first film at the end surface has a first thickness and a second thickness thicker than the first thickness, and a part including the first thickness of the first film is located closer to the side of the third region than a part including the second thickness.

14. The display device according to claim 1, wherein the end surface of the first film inclines in a taper shape.

15. The display device according to claim 1, wherein the resin layer is thinner than the first film.

16. The display device according to claim 15, wherein the resin layer exposes one end on the opposite side to the base film side of the end surface.

17. The display device according to claim 1, wherein the end surface of the first film curves in a wave shape.

18. The display device according to claim 1, further comprising a polarizing film arranged on the first film.

19. The display device according to claim 1, further comprising a second film overlapping the first region on the second surface.

20. The display device according to claim 1, wherein the base film is bent by the third region.
